(19) United States
(12) Patent Application Publication
(10) Pub. No.: US 2026/0331156 A1
(43) Pub. Date: Oct. 22, 2026

(54) APPARATUSES SYSTEMS AND METHODS FOR SELF-REFRESH RATE SYNCHRONIZATION

(71) Applicant: Micron Technology, Inc., Boise, ID (US)

(72) Inventors: Yang Lu, Boise, ID (US); Hyun Yoo Lee, Boise, ID (US); Kang-Yong Kim, Boise, ID (US)

(73) Assignee: Micron Technology, Inc., Boise, ID (US)

(21) Appl. No.: 19/184,320

(22) Filed: Apr. 21, 2025

(51) Int. Cl. G11C 11/406

(52) U.S. Cl. CPC G11C 11/40615; G11C 11/40603; G11C 11/40622

(57) ABSTRACT

A memory module includes several memory die. The memory die are entered into a self-refresh mode together. During the self-refresh mode one of the memory die of the rank is a leader device and provides a self-refresh signal while the other memory die are follower devices which receive the self-refresh signal. The memory die perform self-refresh operations responsive to the self-refresh signal. In this manner, self-refresh operations may be synchronized between the different die during the self-refresh mode.

### BACKGROUND

This disclosure relates generally to semiconductor devices, and more specifically to semiconductor memory devices. In particular, the disclosure relates to volatile memory, such as dynamic random access memory (DRAM). Information is stored in the memory on memory cells as a physical signal such as a charge on a capacitive element. During an access operation, an access command may be received along with address information which specifies which memory cells should be accessed.

Information may decay over time in the memory cells. For example, the memory cells may discharge over time. In order to preserve the integrity of the stored information, the memory cells may be refreshed, for example to restore an initial charge level associated with the stored information. The memory receives a refresh command which instructs it to perform one or more refresh operations. The memory may also enter a self-refresh mode, for example while the memory is in an idle state, where the memory performs refresh operations on itself.

Multiple memory devices may be packaged together in a module. During self-refresh operations, since each memory device controls its own self-refresh timing, the devices may end up performing refresh operations at different times. It may be useful to synchronize the timing of refresh operations during the self-refresh mode across different die of the module.

### BRIEF DESCRIPTION OF THE DRAWINGS

FIG. 1 is a block diagram of a semiconductor device according to some embodiments of the disclosure.

FIGS. 2A and 2B are block diagrams of example memory modules according to some embodiments of the present disclosure.

FIG. 3 is a block diagram of a self-refresh group according to some embodiments of the present disclosure.

FIG. 4 is a schematic diagram of self-refresh logic in a memory device according to some embodiments of the present disclosure.

FIG. 5 is a timing diagram of synchronized self-refresh operations according to some embodiments of the present disclosure.

FIG. 6 is a flow chart of a method of synchronizing self-refresh operations on a memory module according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present apparatuses, systems, methods, and combinations thereof, reference is made to the accompanying drawings. The drawings are shown by way of illustration of specific example embodiments of how the described apparatuses, systems, methods, or combinations thereof may be practiced. These embodiments are described in sufficient detail to enable those skilled in the art to practice presently disclosed apparatuses, systems, methods, and combinations thereof, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory device or memory die includes a memory array. The memory array includes a number of memory cells. The memory cells are at the intersection of bit lines and word lines. The bit lines and word lines may be considered as columns and rows respectively in a logical organization of the array. The memory array is also divided into multiple banks. Accordingly, a row address may specify one or more word lines, a column address may specify one or more bit lines, and a bank address may specify one or more banks.

The memory cells may store information in a manner which decays over time. In an example implementation, the memory cell may include a capacitive element, and the charge on the capacitive element represents if the memory cell stores a logical high or a logical low. The charge may leak over time. In order to preserve information in the array, refresh operations may be performed. For example, the refresh operation may restore the charge to an initial value representing the state of the stored bit.

The memory may perform refresh operations responsive to refresh commands. For example, the memory may receive all bank refresh commands, per-bank refresh commands, or same bank refresh commands. In certain modes, the memory may also perform self-refresh operations. When the device is entered into a self-refresh mode, for example by a self-refresh entry command, a self-refresh oscillator circuit of the memory device periodically generates a self-refresh signal. Responsive to the self-refresh signal, the memory performs a refresh operation. When a self-refresh exit signal is received the self-refresh oscillator circuit deactivates.

Multiple memory devices may be packaged together into a module. The module includes one or more ranks of memory devices, with the memory devices of a rank sharing a common command address bus. Accordingly, the entire rank may generally be entered into, and exited from, the self-refresh mode together. In a conventional memory module, each memory device manages its own self-refresh timing. Over time, minor variations, such as process, voltage, and/or temperature variations, may cause the self-refresh operations to desynchronize from each other, even though the devices were all entered into the self-refresh mode at the same time. This may cause problems. For example, when the self-refresh mode is exited, the module may signal the controller to wait until no refresh operation is being performed before the controller can send commands to that rank. If the refresh operations are out of sync, the odds increase that the controller will need to wait. It may be useful to synchronize self-refresh operations on the module.

The present disclosure is drawn to apparatuses, systems, and methods for self-refresh synchronization. During a self-refresh mode, a group of memory devices perform synchronized self-refresh operations. The group may be all the memory devices of a rank or a subset of the devices of the rank. One memory device of the group, generally referred to as a leader, generates a periodic self-refresh signal and provides that self-refresh signal to the other memory devices of the group, generally referred to as followers. Each of the memory devices of the group performs refresh operations responsive to the self-refresh signal.

In an example implementation, each memory device includes a self-refresh circuit with a transmit portion and a receive portion. For example, the transmit portion may include an output driver and the receive portion may include an input driver. On the leader device, the transmit portion is enabled, while on the follower devices the receive portion is enabled. Which portion is enabled may be a setting of the device, for example in settings register such as a mode register or a fuse array. On the leader device, a self-refresh oscillator is enabled to provide the self-refresh signal through an output driver to a pin of the device. The pin is coupled along a bus to the follower devices of the group. In some embodiments, a dedicated pin and bus may be used. In some embodiments, an existing pin and bus may be used, such as ALERT or ZQ. On the follower device, the self-refresh signal is received along the pin through an input driver. In both the leader and follower devices, the self-refresh signal is provided to refresh control logic which performs one or more refresh operations responsive to the self-refresh signal. In this way, the leader and follower devices may all perform self-refresh operations synchronized to the self-refresh signal from the leader device.

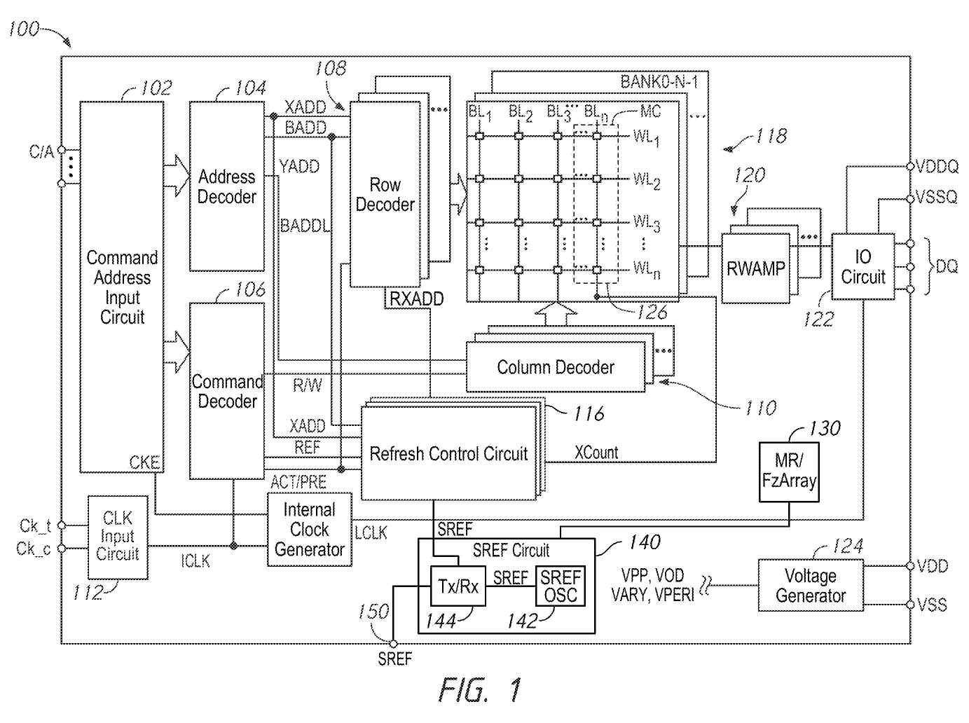

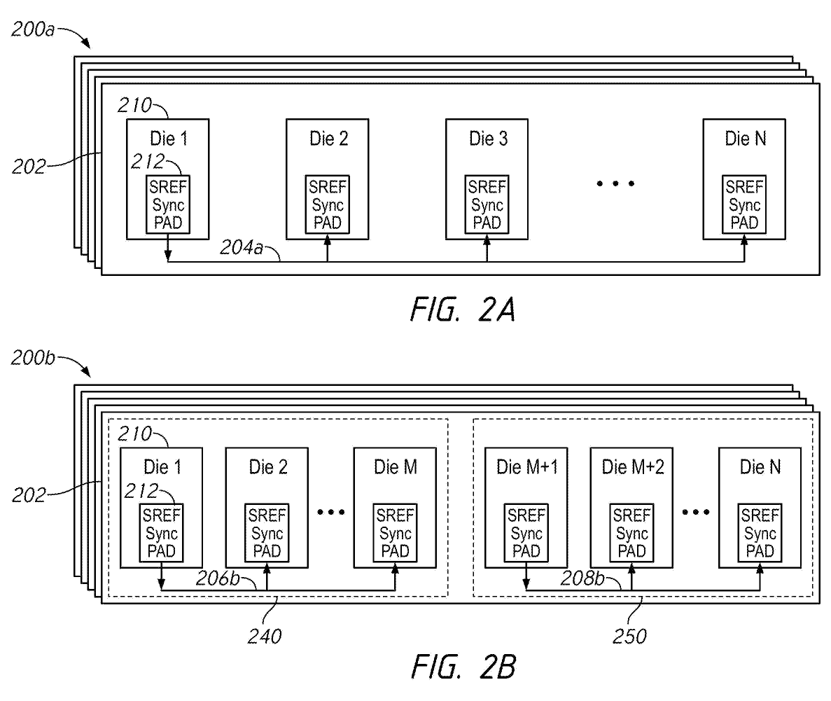

FIG. 1 is a block diagram of a semiconductor device according to some embodiments of the disclosure. The semiconductor device 100 may be a semiconductor memory device, such as a DRAM device integrated on a single semiconductor chip. In some embodiments, the semiconductor device 100 may represent one of a number of memory devices packaged together, such as on a module. An example module is described in more detail in FIG. 2.

The semiconductor device 100 includes a memory array 118. The memory array 118 is organized into a plurality of memory banks. In the embodiment of FIG. 1, the memory array 118 is shown as including N memory banks labeled BANK0 to BANKN-1. For example, a memory array 118 may include 4, 8, 16, 32 or any other number of memory banks. More or fewer banks may be included in the memory array 118 of other embodiments.

Each memory bank includes a plurality of word lines WL, a plurality of bit lines BL, and a plurality of memory cells MC arranged at intersections of the plurality of word lines WL and the plurality of bit lines BL. The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank.

The bit lines BL are coupled to a respective sense amplifier (SAMP). Read data from the bit line BL is amplified by the sense amplifier SAMP, and transferred to read/write amplifier (RWAMP) circuit 120 over local data lines (LIO), transfer gate (TG), and global data lines (GIO). Conversely, write data outputted from the RWAMP circuit 120 is transferred to the sense amplifier SAMP over the complementary main data lines GIO, the transfer gate TG, and the complementary local data lines LIO, and written in the memory cell MC coupled to the bit line BL.

The semiconductor device 100 may employ a plurality of external terminals, such as solder pads, that include command and address (C/A or CA) terminals coupled to a command and address bus to receive commands and addresses, clock terminals to receive clocks CK and /CK, data terminals DQ coupled to a data bus to provide data, and power supply terminals to receive power supply potentials VDD, VSS, VDDQ, and VSSQ. The external terminals may also generally be referred to as ‘pins’ such as C/A pins. In some embodiments, the external terminals may couple directly to a host or controller of the memory device 100. In some embodiments, the external terminals may couple to various buses/connectors of a module or other package. In some embodiments, each terminal may generally receive a first voltage which represents a logical high or a second voltage which represents a logical low. Other schemes, such as multi-level signaling (e.g., PAM4) may be used in other example embodiments.

The clock terminals are supplied with external clocks CK and /CK that are provided to an input circuit 112. The external clocks may be complementary. The input circuit 112 generates an internal clock ICLK based on the CK and /CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data. The input/output circuit 122 may include a number of interface connections, each of which may be couplable to one of the DQ pads (e.g., the solder pads which may act as external connections to the device 100).

The C/A terminals may be supplied with memory addresses. The memory addresses supplied to the C/A terminals are transferred, via a command/address input circuit 102, to an address decoder 104. The address decoder 104 decodes the address into a bank address, row address, and column address. The bank address BADD selects the row decoder 108 and column decoder 110 and thus selects the bank. The address decoder 104 supplies a decoded row address XADD to the row decoder 108 selected by BADD and supplies a decoded column address YADD to the column decoder 110 selected by BADD. The decoded row address XADD may be used to determine which row is opened or activated, coupling the memory cells along the activated word line to the intersecting bit lines. The column decoder 110 provides a column select signal CS based on the column address YADD. The CS signal selects which bit lines are coupled to local input/output lines, allowing those bit lines to be accessed.

The C/A terminals may be supplied with commands. Examples of commands include timing commands for controlling the timing of various operations, access commands for accessing the memory, such as row activation commands, read commands for performing read operations, write commands for performing write operations, and pre-charge commands, refresh commands such as all-bank refresh, same bank refresh, and per-bank refresh, as well as other commands and operations. The access commands may be associated with one or more row address XADD, column address YADD, and bank address BADD to indicate the memory cell(s) to be accessed. In some embodiments, the command and address may be transmitted together as a command packet along the C/A terminals. The input circuit 102 separates the command portion of the packet from the address portion and provides the command portion to the command decoder 106 and the address portion to the address decoder 104.

The commands may be provided as internal command signals to a command decoder 106 via the command/address input circuit 102. The command decoder 106 includes circuits to decode the internal command signals to generate various internal signals and commands for performing operations. For example, the command decoder 106 may provide signals to indicate if data is to be read, written, etc. Responsive to an activation command received at the C/A terminals, as part of an access operation the command decoder 106 provides an internal row activation command or internal row activation signal ACTN or ACTL. Responsive to a pre-charge command the command decoder 106 provides an internal pre-charge command or internal pre-charge signal Pre. The row decoder 108 activates a word line responsive to the internal activation signal ACT and deactivates (or pre-charges) the word line responsive to the internal pre-charge signal Pre.

In an example write operation, the device 100 writes data received at the DQ terminals to the memory cells specified by a received bank, row and column address. As part of the write operation, the command decoder 106 receives a write command and activation command and provides internal signals such as W and ACT/Pre. The write data is received by the IO circuit 122 and provided to the RWAMP circuit 120. The row decoder 108 selected by BADD activates the row selected by XADD responsive to the internal activation signal ACT. The column decoder 110 selected by BADD couples the bit lines selected by YADD to the LIO and GIO lines to the RWAMP circuit 120. The sense amplifiers drive the voltages on the coupled bit lines to write the write data to the memory cells at the intersection with the active word line.

In an example read operation, the device 100 reads data from the memory cells specified by a received bank, row, and column address and provides that read data to the DQ terminals. As part of the read operation, the command decoder 106 receives a read command and an activation command and provides internal signals such as a read signal R, and ACT/Pre. The row decoder 108 selected by BADD activates the row selected by XADD responsive to the internal row activation signal ACT. The column decoder 110 selected by BADD couples the bit lines selected by YADD to the LIO and GIO lines to the RWAMP circuit 120. The RWAMP circuit 120 provides the read data to the IO circuit 122 and the IO circuit 122 provides the read data to the DQ terminals.

The device 100 includes refresh control circuits 116 each associated with a bank of the memory array 118. Each refresh control circuit 116 performs refresh operations on the associated bank by providing a refresh address RXADD, along with one or more refresh signals. The refresh control circuits 116 may perform one or more refresh operations responsive to a refresh command. For example, the memory may receive an all-bank refresh command REFab along the C/A terminals, and the command decoder 106 provides a refresh signal REF to all of the refresh control circuits 116. Responsive to the refresh signal REF, the refresh control circuits 116 perform refresh operations. The memory may also receive commands such as a per-bank refresh command REFpb or same-bank refresh command REFsb, which specify which bank or banks the command decoder 106 should provide the refresh signal to.

Refresh operations may include one or more normal refresh operations, one or more targeted refresh operations, or combinations thereof. In a normal refresh operation, the refresh address is generated based on sequence logic. For example a refresh address counter may increment to generate a new refresh address, such as RXADD(i) = RXADD(i-1) + 1. In a targeted refresh operation, an identified aggressor address is used to generate refresh addresses. The refresh addresses may be adjacent to the aggressor, for example RXADD = Aggressor +/-1.

The refresh control circuit 116 also tracks accesses to word lines of the respective banks to determine if a targeted refresh operation should be performed. Memory cells along each word line are set aside as counter memory cells 126. The counter memory cells store a per-row access count (PRAC) value associated with a number of times that the respective word line has been accessed. When a word line is accessed or refreshed, its PRAC value is read out to the refresh control circuit 116 which updates (e.g., increments) the count value and determines if the count has crossed a threshold as part of an access count update (ACU) operation. If the PRAC value has crossed a mitigation threshold, then the address is added to an aggressor queue for a later targeted refresh operation. When a targeted refresh operation is performed, one or more victim word lines of the aggressor word line are refreshed.

The memory device 100 may enter a self-refresh mode, where the memory performs refresh operations on itself without the need for external commands. For example, the memory device 100 may receive a self-refresh entry (SRE) command along the C/A pins. Responsive to the SRE command, the memory device 100 may begin performing self-refresh operations until receiving a self-refresh exit (SRX) command. In some embodiments, the memory 100 may automatically begin performing self-refresh operations in certain modes or states, such as in an idle state. The memory device includes a self-refresh circuit 140, which provides a self-refresh signal SREF when the memory is in the self-refresh mode. The refresh control circuits 116 receive SREF and perform one or more refresh operations responsive to SREF. In some embodiments, only normal refresh operations are performed during the self-refresh mode. In some embodiments, a mix of normal and targeted refresh operations may be performed, at least until the targeted refresh queue is empty.

The self-refresh circuit 140 provides SREF with periodic timing. If the device 100 is configured as a leader device, then a self-refresh oscillator circuit 142 of the device 100 provides the SREF signal to the refresh control circuit 116. If the device 100 is configured as a follower device 100, then the self-refresh circuit 140 receives SREF along an SREF pin 150 and provides the received SREF signal to the refresh control circuit 116. The self-refresh circuit 140 includes transmit and receive paths 144 which are selectively enabled based on whether the device 100 is a leader or follower to either provide or receive the signals SREF. In some embodiments, if the device 100 is configured as a follower, then the self-refresh oscillator 142 may be disabled.

The self-refresh signal SREF may be sent or received along a SREF pin 150. In some embodiments, the SREF pin 150 may be a dedicated pin used for synchronizing the SREF operations among multiple devices during a self-refresh mode. In some embodiments, the SREF pin 150 may be used for other purposes. For example, the SREF pin 150 may also be a pin which is relatively infrequently used and/or not used during self-refresh modes, such as a ZQ pin or an ALERT pin. The SREF pin 150 is coupled to a SREF bus which is coupled to the SREF pins of other memory devices on the module. The terms SREF pin and SREF bus are generally used herein to refer to the pin(s) and bus used to carry the self-refresh signal. However the term SREF pin and SREF bus as used herein may apply to either a dedicated pin and bus or to an existing pin and bus (e.g., ALERT or ZQ) that may have a different name.

One or more settings of the memory device 100 may determine whether the device 100 is configured as a self-refresh leader or follower. For example, the setting may be stored in a settings register 130. The settings register 130 may be non-volatile storage, such as a fuse array, volatile storage, such as a mode register, or combination thereof. The settings register 130 may include settings which select whether the transmit path 144 of the self-refresh circuit 140 or the receive path 144 of the self-refresh circuit 140 is used, and whether or not the self-refresh oscillator is enabled or not during self-refresh modes. In some embodiments, the settings register 130 may also include a setting which enables or disables the self-refresh synchronization. For example, if the self-refresh synchronization is disabled, then each memory device may provide its own self-refresh signal during self-refresh modes.

The power supply terminals are supplied with power supply potentials VDD and VSS. The power supply potentials VDD and VSS are supplied to an internal voltage generator circuit 224. The internal voltage generator circuit 224 generates various internal potentials VARY, and the like based on the power supply potentials VDD and VSS supplied to the power supply terminals.

The power supply terminals are also supplied with power supply potentials VDDQ and VSSQ. The power supply potentials VDDQ and VSSQ are supplied to the input/output circuit 222. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks. The voltages VDD and VSS (or voltages derived therefrom) may generally be used by circuits of the memory such as the array 118, row decoder 108, refresh control circuit 116 and others. The voltages VDDQ and VSSQ may generally be used by the input/output circuit 122 and not by other components of the memory device 100.

FIGS. 2A and 2B are block diagrams of example memory modules according to some embodiments of the present disclosure. FIG. 2A shows a memory module 200a where all of the memory die 210 of a rank 202 are part of a same self-refresh groups. FIG. 2B shows a memory module 200b where the memory dice 210 of the rank 202 are divided into multiple self-refresh groups 240 and 250. In the example implementation of FIG. 2B, there are two self-refresh groups 240 and 250 per rank, however more or groups per rank may also be used. Each memory module 200a and 200b includes a number of individual memory devices 210, which may be implemented by the memory device 100 of FIG. 1. The two memory modules 200a and 200b may be generally similar except for the size of the self-refresh groups.

Each memory module 200a and 200b includes a number of memory dice 210. The modules 200a and 200b are divided into one or more ranks 202. The ranks include memory devices which are coupled to a common command/address bus (not shown in FIGS. 2A and 2B). In the example of FIGS. 2A and 2B, each rank 202 includes N memory dice 210, here labelled Die 1 to Die N. Each of the memory die 210 includes a self-refresh circuit 212 (e.g., 140 of FIG. 1). Within a self-refresh group, the self-refresh circuits are coupled in common via SREF pins to a SREF bus. In the module 200a, all the memory dice 210 of the rank 202 are coupled to a same SREF bus 204a. In the module 200b, there are two SREF buses 206b and 208b, one for each of the two self-refresh groups 240 and 250 respectively.

One of the memory devices 210 of the group is set up as a leader device and provides an SREF signal along the bus 204a, 206b, or 208b during a self-refresh mode, while the other devices 210 are set up as follower devices and receive the SREF signal from the respective bus. In some embodiments, it may be useful to make the leader device one which is near a middle of the respective self-refresh group, in order to reduce the furthest distance the self-refresh signal needs to travel. Similarly, the use of multiple self-refresh groups within a rank, as in FIG. 2B, may help reduce the load on the output driver in the leader device of the group.

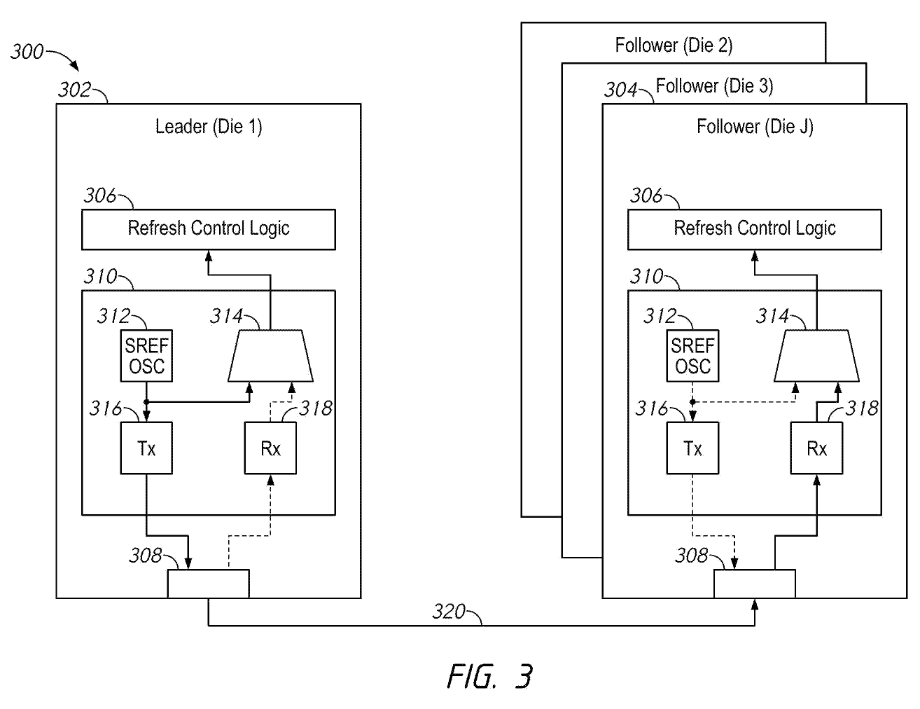

FIG. 3 is a block diagram of a self-refresh group according to some embodiments of the present disclosure. The self-refresh group 300 shows a set of memory die 302 and 304. The memory die 302 and 304 may, in some embodiments, be implemented by the memory device 100 of FIG. 1. The memory die 302 and 304 are part of a same rank (e.g., 202 of FIG. 2) on a memory module (e.g., 200aof FIG. 2A and/or 200bof FIG. 2B). The self-refresh group 300 may represent all the memory die of a rank as in FIG. 2A, or a subset of the memory die of the rank as in FIG. 2B.

The memory die 302 and 304 each include refresh control logic circuits 306 (e.g., 116 of FIG. 1) and self-refresh circuits 310 (e.g., 140 of FIG. 1 and/or 212 of FIGS. 2A and 2B). The self-refresh circuits 310 include a self-refresh oscillator circuit 312 (e.g., 142 of FIG. 1), a transmit circuit 316, a receive circuit 318, and a selector 314. The selector 314, transmit circuit 316, and receive circuit 318 may implement the transmit and receive logic 144 of FIG. 1 in some embodiments. The memory die 302 and 304 may be structurally similar to each other, or structurally identical to each other. The memory die 302 is configured as a leader die, while the memory die 304 are configured as follower die. The determination may be based on a setting stored in a setting register (e.g., 130 of FIG. 1) of the respective devices, not shown in FIG. 3.

FIG. 3 shows the path of a self-refresh signal from the leader die 302 to the follower dice 304. The self-refresh signal is shown as a solid line, while dotted lines are used to represent paths which aren’t used based on the setting of the device. FIG. 3 shows an example implementation where the self-refresh group 300 includes J memory devices, labelled Die 1 to Die J. For ease of reference, Die 1 is used as the leader die 302 while the remaining Die 2 to Die J are used as follower dice 304. However, any one of the die may be set up as the leader die in other example implementations. For ease of explanation, only one follower die 304 will be described in detail, however the other follower die may generally be similar.

During a self-refresh mode, the self-refresh oscillator circuit 312 of the leader die 302 is activated and begins periodically generating a self-refresh signal SREF. The signal SREF is provided to the selector circuit 314 and to the transmit circuit 316. The selector circuit 314 in the leader die 302 passes the SREF signal from the self-refresh oscillator circuit 312 to the refresh control logic 306. In the leader die 302 the transmit circuit 316 drives the SREF signal through an SREF pin and onto a SREF bus 320 (e.g., 204a of FIGS. 2A, 206b and/or 208b of FIG. 2B).

In the follower die 304, the SREF signal from the leader die 302 is received from the bus 320 through the SREF pin 308 (e.g., 150 of FIG. 1) to the receive circuit 318. The receive circuit 318 provides SREF to the selector circuit 314, which passes the signal from the receive circuit 318 to the refresh control logic 306. In both the leader die 302 and the follower dice 304, the refresh control logic circuits 306 perform one or more refresh operations responsive to the SREF signal. For example, the refresh control logic circuits 306 may generate one or more refresh addresses RXADD and the word line or word lines associated with the refresh address may be refreshed.

In the leader die 302, the self-refresh oscillator circuit 312 and the transmit circuit 316 may be enabled, and the selector 314 is set to pass the signal from the self-refresh oscillator circuit 312. The receiver circuit 318 may be disabled in the leader die 302. In the follower die 304, the receiver circuit 318 is enabled and the selector circuit 314 is set to pass the signal from the receiver circuit 318. In the follower die 304, the self-refresh oscillator circuit 312 and the transmit circuit 316 may be disabled.

In some embodiments, when the self-refresh synchronization mode is disabled, then all of the memory devices to be leader devices. In some embodiments, when the self-refresh synchronization mode is disabled, the self-refresh oscillator circuits 312 may be enabled, but the transmit circuits 316 may be disabled.

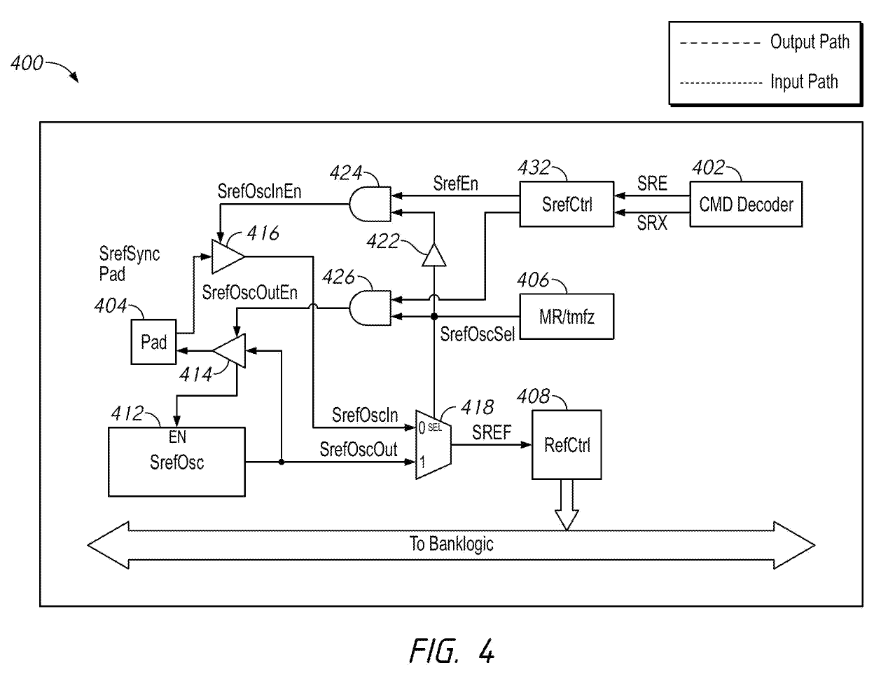

FIG. 4 is a schematic diagram of self-refresh logic in a memory device according to some embodiments of the present disclosure. The self-refresh logic 400 shows various components that may implement a self-refresh circuit, such as 140 of FIGS. 1, 212 of FIGS. 2A and/or 2B , and/or 310 of FIG. 3. Certain other components of a memory die which are useful to describing to self-refresh synchronization are also shown, such as a pad 404 (e.g., 308 of FIG. 3), a command decoder 402 (e.g., 106 of FIG. 1), a settings register 406 (e.g., 130 of FIG. 1), and a refresh control circuit 408 (e.g., 116 of FIG. 1 and/or 306 of FIG. 3).

The self-refresh circuit (e.g., 140 of FIGS. 1, 212 of FIG. 2A/2B, and/or 310 of FIG. 3) includes a self-refresh oscillator circuit 412 (e.g., 142 of FIG. 1 and/or 312 of FIG. 3), input driver 416 (e.g., 318 of FIG. 3), output driver 414 (e.g., 316 of FIG. 3), multiplexer circuit 418 (e.g., 314 of FIG. 3), self-refresh control circuit 432, and logic circuits 422, 424, and 426. The settings register 406, such as mode register or fuse array, provides a self-refresh mode select signal SrefOscSel. The state of the SrefOscSel signal determines whether the self-refresh logic is set up as a leader or a follower. For example, if SrefOscSel is active, then the device may be configured as a leader device, and if SrefOscSel is inactive, then the device may be a follower. The self-refresh control circuit 432 provides a self-refresh enable signal SrefEn which indicates if the device is in a self-refresh mode or not. For example, responsive to the self-refresh entry command SRE from the command decoder 402, the self-refresh control circuit 432 starts providing SrefEn at an active level, and responsive to the self-refresh exit command SRX from the command decoder 402, the self-refresh control circuit 432 stops providing SrefEn at an active level.

An AND gate 426 provides a leader enable signal SrefOscOutEn when both SrefEn and SrefOscSel are active. Accordingly, SrefOscOutEn will be active when the device is in a self-refresh mode and when the device is configured as a leader device. The signal SrefOscOutEn enables both the output driver 414 and the self-refresh oscillator circuit 412. Responsive to being activated, the self-refresh oscillator circuit 412 provides the self-refresh signal SrefOscOut (e.g., SREF of FIGS. 1-3) to the output driver 414 and to the selector circuit 418. When the output driver 414 is enabled, it provides SrefOscOut to the SREF pin 404.

An inverter circuit 422 passes SrefOscSel to an input of a second AND gate 424. The other input of the second AND gate 424 is coupled to SrefEn. The second AND gate 424 provides a follower enable signal SrefOscInEn. Accordingly, SrefOscInEn is active when SrefEn is active and SrefOscSel is inactive, indicating that the device is in a self-refresh mode and configured as a follower device. The signal SrefOscInEn activates the input driver 416. When the input driver 416 is activated, it receives the signal SREF from the pad 404 and provides it to the selector 418 as SrefOscIn.

The selector circuit 418 provides either SrefOscIn or SrefOscOut as SREF to the refresh control circuit 408 based on the state of SrefOscSel. If SrefOscSel is active, then SrefOscOut is passed as SREF. If SrefOscSel is inactive, then SrefOscIn is passed as SREF. Responsive to SREF, the refresh control circuit 408 performs one or more refresh operations. For example, responsive to SREF the refresh control circuit 408 may generate one or more refresh addresses, and the word line or word lines associated with each of those refresh addresses are refreshed.

In this manner, when the device is not in a self-refresh mode, and SrefEn is disabled, then the input circuit 416, output circuit 414, and self-refresh oscillator are all disabled. When the device is in a self-refresh mode, if the device is a leader device then the self-refresh oscillator 412 and output circuit 414 are enabled while the input circuit 416 is disabled, and if the device is a follower device than the input circuit 416 is enabled while the output circuit 414 and oscillator circuit 412 are disabled.

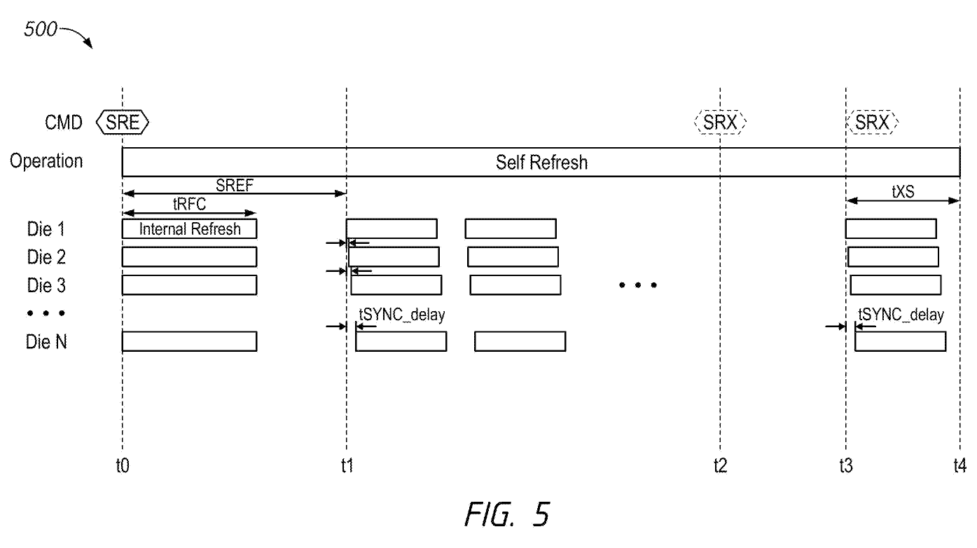

FIG. 5 is a timing diagram of synchronized self-refresh operations according to some embodiments of the present disclosure. The timing diagram 500 represents operations in a memory die (e.g., 100 of FIG. 1) on a module (e.g., 200 of FIG. 2). The self-refresh operations may be synchronized across the different die using self-refresh circuits such as 140 of FIGS. 1, 212 of FIGS. 2, 310 of FIG. 3 and/or 400 of FIG. 4 in some embodiments.

The timing diagram 500 shows commands along a command bus CMD and a bar which represents a mode of the memory die. An example set of N memory dice Die 1 to Die N are shown. Boxes represent a time during which a self-refresh operation is being performed in that die. For the sake of explanation, Die 1 is the leader die, while dice Die 2 to Die N are follower die. However, any one of the die could be set up as the leader die in different example embodiments.

At an initial time t0, a self-refresh entry SRE command is received. This cases the die to enter an self-refresh mode. At the initial time t0, all of the die are entered in self-refresh modes, and the leader die begins generating a self-refresh signal SREF. Responsive to SREF, Die 1 to Die N each perform self-refresh operations. Each die performs self-refresh operations for a time tRFC. At a time t1, the next activation of SREF is generated by the leader die. The period between t0 and t1 represents the period of the self-refresh oscillator circuit (e.g., 142 of FIGS. 1, 312 of FIG. 3, and/or 412 of FIG. 4). The die Die 2 to Die N all perform self-refresh operations responsive to SREF.

As an example, FIG. 5 shows an exaggerated scenario to represent how there may be some delays between different die. For example, it may take time for the signal SREF to propagate along a SREF bus to the follower die. In the example of FIG. 5, the numbering of the die indicates their position in a line, with Die 2 closest to Die 1 and Die N furthest from Die 1. Accordingly, Die 2 performs a self-refresh operation at almost the same time that Die 1 does, but there is an increasing delay along the other die up to Die N, which begins performing a self-refresh operation a synchronization delay time tSYNC_delay after Die 1 began performing self-refresh operations at time t1. However, the time tSYNC_delay may be relatively short, for example as compared to tREFC. There may thus be a large degree of overlap between the times when the different die are all performing self-refresh operations. In contrast, when the memory devices are un-synchronized and each device is independently generating SREF, there may be situations where not all of the self-refresh operations overlap.

After a period of time, a self-refresh exit SRE command may be received. FIG. 5 shows two example time points t2 and t3, where an SRE command may be received. At the time t2, no device is performing self-refresh operations, and so responsive to SRE, the die all exit the self-refresh mode. Since no device was performing self-refresh operations at t2, after sending the SRE command, the controller may begin providing access commands to the memory module relatively quickly.

At the example time t3, a SRE command is received at about the same time that a SREF signal is sent from the leader device. Accordingly, the controller must wait a period of time before it can being providing commands to the die. In the example of FIG. 5, a time tXS must elapse until a time t4 when the controller can begin providing commands. In an example implementation, the memory module may include a self-refresh exit flag. When the SRX command is received, if any memory die is performing self-refresh operations, the memory module may raise the self-refresh exit flag and lower it when no device is performing self-refresh operations. The controller may wait to provide commands until the self-refresh flag is lowered.

When the self-refresh operations are synchronized, it greatly decreases the period of time in which at least one device is performing a self-refresh operation. For example, when the self-refresh operations are synchronized, the amount of time when at least one memory die is performing a self-refresh operation may generally be about (tRFC + tSYNC_delay)/SREF. This may generally be relatively small, for example in some example implementations it may be between 10% and 15%. Accordingly, when the controller sends a SRX command, there is a relatively high chance that no die is performing a self-refresh operation and commands to these die may begin relatively quickly.

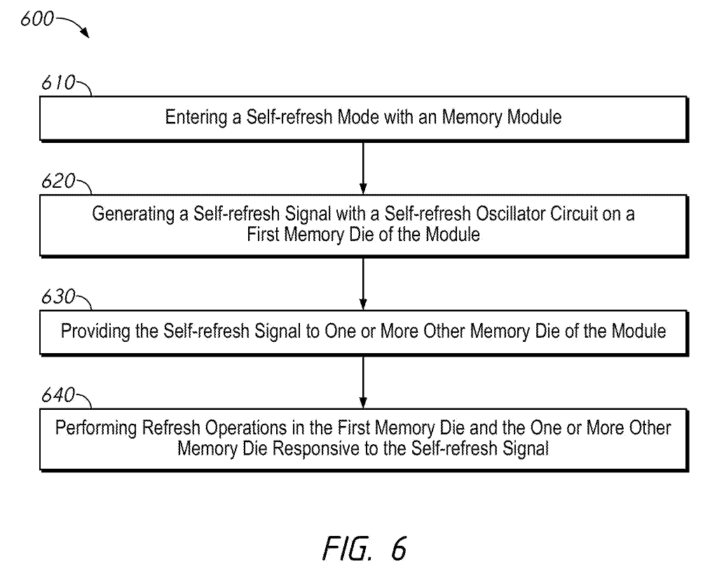

FIG. 6 is a flow chart of a method of synchronizing self-refresh operations on a memory module according to some embodiments of the present disclosure. The method 600 may, in some embodiments, be implemented by one or more of the apparatuses and systems described herein. For example, the method 600 may be implemented by the memory devices 100 of FIGS. 1, 210 of FIGS. 2, 302 /304 of FIG. 3 on a memory module such as 200a/200b of FIGS. 2A and 2B and/or 300 of FIG. 3.

The method 600 may generally begin with box 610 which describes entering a self-refresh mode with a memory module. For example, the module (e.g., 200a/200b of FIG. 2A/2B and/or 300 of FIG. 3) may receive a self-refresh entry (SRE) command along a command address bus. The method includes providing the SRE command to each of the memory devices of a same rank of the module. Responsive the SRE command the memory die of the rank may enter the self-refresh mode.

Block 610 may be followed by block 620, which describes generating a self-refresh signal with a self-refresh oscillator circuit on a first memory die of the module. The first memory die may be set up as a leader device (e.g., 302 of FIG. 3). The method 600 may include providing the self-refresh signal through a pin of the first memory die to a bus. Block 620 may generally be followed by block 630, which describes providing the self-refresh signal to one or more other memory die of the module. For example, the one or more other memory die may be set up as follower die (e.g., 304 of FIG. 3). The method 600 may include providing the self-refresh signal along the bus to pins of the one or more other die.

Block 630 may be followed by block 640, which describes performing refresh operations in the first memory die and the one or more other memory die responsive to the self-refresh signal. For example, the method may include providing the self-refresh signal to a respective refresh control circuit in each of the first die and the one or more other die. The method 600 may include generating one or more refresh addresses with the refresh control circuits responsive to the self-refresh signal, and refreshing one or more word lines associated with each of the refresh addresses.

The method 600 may include setting the first memory die to be a leader device and setting the one or more other memory die to be follower die. In some example embodiments, the setting may be done in a manufacturing and/or packaging environment, for example by setting fuses when packaging the die on the module. In some example embodiments, the setting may be done by performing a mode register write operation. In some embodiments, the method may include disabling self-refresh oscillator circuits on the one or more other memory die.

In some embodiments the method 600 may include exiting the self-refresh mode with the memory module. For example the method may include receiving a self-refresh exit (SRX) command along the command/address bus. In some embodiments, the method 600 may include raising a SRX flag if any of the first memory die or the one or more other memory die are performing a refresh operation. In some embodiments, a controller may wait to provide commands to the rank while the SRX flag is raised.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An memory module comprising:
a command/address bus;
a self-refresh bus;
a plurality of memory die each coupled in common to the command/address bus and the self-refresh bus, wherein responsive to a self-refresh entry command along the command/address bus one of the plurality of memory die is configured to begin periodically providing a self-refresh signal along the self-refresh bus and wherein each of the plurality of memory die is configured to perform one or more self-refresh operations responsive to the self-refresh signal.

2. The memory module of claim 1, wherein each of the plurality of memory die includes a settings register configured to store a self-refresh mode select signal, wherein the one of the plurality of memory die has the self-refresh mode select signal in a first state and a remainder of the plurality of memory die have the self-refresh mode select signal in a second state.

3. The memory module of claim 1, wherein responsive to a self-refresh exit command along the command/address bus, the one of the plurality of memory die stops providing the self-refresh signal.

4. The memory module of claim 1, wherein the plurality of memory die are a rank of the memory module.

5. The memory module of claim 1, further comprising:
a second self-refresh bus;
a second plurality of memory die each coupled in common to the command/address bus and to the second self-refresh bus, wherein the second plurality of memory die are part of a same rank as the plurality of memory die, and wherein responsive to the self-refresh entry command along the command/address bus one of the second plurality of memory die is configured to begin periodically providing a second self-refresh signal along the second self-refresh bus, and wherein each of the second plurality of memory die is configured to perform one or more self-refresh operations responsive to the second self-refresh signal.

6. The memory module of claim 1, wherein each of the plurality of memory devices comprises:
a self-refresh pin coupled to the self-refresh bus;
a refresh control circuit configured to perform the one or more self-refresh operations responsive to the self-refresh signal;
a self-refresh oscillator circuit which is configured to generate the self-refresh signal on the one of the plurality of memory die and configured to be disabled on a remainder of the plurality of self-refresh die; and
a selector circuit configured to couple the self-refresh oscillator circuit to the refresh control circuit on the one of the plurality of memory die and configured to couple the self-refresh pin to the refresh control circuit on the remainder of the plurality of memory die.

7. The memory module of claim 6, wherein each of the plurality of memory devices further comprises an output driver and an input driver each coupled to the self-refresh pin, wherein the output driver is enabled on the one of the plurality of memory devices and the input driver is enabled on the remainder of the plurality of memory die.

8. The memory module of claim 1, wherein the self-refresh bus is an alert bus or a ZQ bus.

9. An apparatus comprising:
a pin;
a refresh control circuit configured to perform one or more refresh operations responsive to a self-refresh signal
a self-refresh circuit configured to generate the self-refresh signal and provide the self-refresh signal to the pin and the refresh control circuit when the apparatus is in a self-refresh mode and a self-refresh mode select signal is in a first state, and configured to receive the self-refresh signal from the pin and provide the self-refresh signal to the refresh control circuit when the apparatus is in the self-refresh mode and the self-refresh mode select signal is in a second state.

10. The apparatus of claim 9, further comprising a settings register configured to store the self-refresh mode select signal.

11. The apparatus of claim 9, wherein the self-refresh circuit includes a self-refresh oscillator circuit configured to periodically provide the self-refresh signal when the apparatus is in a self-refresh mode and the self-refresh mode select signal is in the first state and to be disabled when the self-refresh mode select signal is in the second state.

12. The apparatus of claim 9, wherein the self-refresh circuit further comprises a selector circuit configured to couple the self-refresh oscillator circuit to the refresh control circuit when the self-refresh mode select signal is in the first state and configured to couple the pin to the refresh control circuit when the self-refresh mode select signal is in the second state.

13. The apparatus of claim 9, wherein the pin is an alert pin or a ZQ pin.

14. The apparatus of claim 9, wherein the self-refresh circuit further comprises an output driver enabled when the self-refresh mode select signal is in the first state and an input driver enabled when the self-refresh mode select signal is in the second state.

15. A method comprising:
entering a self-refresh mode with a memory module;
generating a self-refresh signal with a self-refresh oscillator circuit on a first memory die of the module;
providing the self-refresh signal to one or more other memory die of the memory module; and
performing refresh operations in the first memory die and the one or more other memory die responsive to the self-refresh signal.

16. The method of claim 15, further comprising setting the first memory die to a first mode and the one or more other memory die to a second mode.

17. The method of claim 15, further comprising providing the self-refresh signal from the first memory die to the one or more other memory die along a self-refresh bus.

18. The method of claim 15, wherein the first memory die and the one or more other memory die are part of a same rank of the memory module.

19. The method of claim 15, further comprising:
entering the self-refresh mode by providing a self-refresh entry command along a command/address bus to the first memory die and the one or more other memory die; and
exiting the self-refresh mode by providing a self-refresh exit command along the command/address bus to the first memory die and the one or more other memory die.

20. The method of claim 15, further comprising disabling self-refresh oscillator circuits on the one or more other memory die.
